(19) United States
(12) Patent Application Publication
(10) Pub. No.: US 2026/0339404 A1
(43) Pub. Date: Oct. 29, 2026

(54) THERMAL INTERFACE MATERIAL (TIM) ENGAGING MECHANISM FOR RECEIVING MODULES

(71) Applicant: Dell Products L.P., Round Rock, TX (US)

(72) Inventors: ASHISH SHRIVASTAVA, Bangalore (IN); JUAN M. GONZALEZ, Round Rock, TX (US)

(21) Appl. No.: 19/193,456

(22) Filed: Apr. 29, 2025

(51) Int. Cl. G06F 1/20; H05K 7/20

(52) U.S. Cl. CPC G06F 1/206; H05K 7/2039

(57) ABSTRACT

Methods, systems, and devices are provided for managing operable connection between a hardware component housed by a chassis of a data processing system and a module. To do so, the data processing system may include a receiver for the module to establish the operable connection between the hardware component and the module. To do so, this receiver may include a heatsink for dissipating heat generated by the module, and a positioning system adapted to automatically transition the heatsink from a first position to a second position during an insertion of the module into a chassis of the data processing system. While in the second position, the heatsink may be in thermal communication with the module via a thermal conduction channel. While in the first position, the heatsink may not be in thermal communication with the module via the thermal conduction channel.

### FIELD

Embodiments disclosed herein relate (generally) to thermal management of data processing systems. More particularly, embodiments disclosed herein relate to systems and methods for mitigating (e.g., heat) damage to data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIGS. 1A-1B show diagrams illustrating a data processing system in accordance with an embodiment.

FIGS. 2A-2F show diagrams illustrating a receiver of a data processing system in accordance with an embodiment.

FIGS. 3A-3B show flow diagrams illustrating methods in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary de vices, such as in a network topology.

In general, embodiments disclosed herein relate to methods and systems for managing a data processing system. The data processing system may provide computer-implemented services. To do so, operation of hardware components may facilitate various functionalities of the data processing system, a byproduct of such operation resulting in a generation of heat.

If the generated heat is not properly regulated (e.g., dissipated), the hardware components may be damaged due to a buildup of the generated heat that is beyond the thermal range (e.g., beyond thermal operating limits) for optimal operation of the data processing system.

Consequently, damage to the hardware components may cause workloads performed by the hardware components and/or facilitated functionalities of the data processing system to be lost (referred to as “workload loss”) and/or otherwise deprecated (resulting in less-than-optimal operation of the data processing system at best). Such loss and/or deprecation may, in turn, negatively impact (e.g., delay and/or prevent entirely) the data processing system's providing of the computer-implemented services.

For example, imagine a connection port on a chassis for a data processing system is connected to a transceiver module, thereby connecting the data processing system to a separate device via an operable connection. Further assume that the module's operation results in significant generation of heat. To decrease the likelihood of damage to the connection (“receiving”) port, the module, and/or any other connected components/devices, a heatsink may be positioned with the connection port, and thermal interface material (TIM) may be positioned between where the module may be inserted into the connection port and the heatsink to optimize an efficiency associated with a dissipation of heat generated during the module's operation.

However, due to the desirable “hot-swapping” nature of such modules (e.g., being able to easily, and frequently, change out modules operably connected via the connection slot), the connection port may become excessively used. Consequently, such integral components as the TIM may become degraded and/or even removed entirely over the course of one or more such “hot-swapping” of these modules.

To increase a likelihood of enabling the TIM to stay intact throughout such “hot-swapping”, and therefore, increase a likelihood of facilitating and maintaining efficient thermal regulation of the data processing system, the data processing system may include a receiver (e.g., a connection port for receiving for such “hot-swapping” modules) to establish operable connection between the data processing system and a module. To do so, this receiver may include a heatsink for dissipating heat generated by the module, and a positioning system adapted to automatically transition the heatsink from a first position to a second position during an insertion of the module into a chassis of the data processing system.

For example, while in the second position, the heatsink may be in thermal communication with the module via a thermal conduction channel. While in the first position, the heatsink may not be in thermal communication with the module via the thermal conduction channel.

Thus, heat generated by components of the data processing system may be efficiently regulated by utilizing such receivers that include both a heatsink and positioning system, thereby increasing the likelihood of the computer-implemented services being provided by the data processing system as expected and/or desired by a consumer of such services.

In an embodiment, a data processing system is provided.

This data processing system may include a hardware component; and a receiver for a module to establish an operable connection between the hardware component and the module, the receiver including a heatsink for dissipating heat generated by the module; and a positioning system adapted to automatically transition the heatsink from a first position to a second position during an insertion of the module into a chassis of the data processing system, while in the second position the heatsink is in thermal communication with the module via a thermal conduction channel, and while in the first position the heatsink is not in thermal communication with the module via the thermal conduction channel.

The positioning system may include a movement control component adapted to limit movement of a position control component to be along a movement path.

The positioning system may further include the position control component adapted to move the heatsink from the first position to the second position while moving along the movement path.

The position control component may include an engagement member to engage with the module during the insertion of the module, the engagement of the engagement member facilitating the movement of the position control component along the movement path.

The position control component may further include a guide pin that engages with the movement control component to constrain the movement of the position control component to the movement path.

The movement control component may include a first slot adapted to receive the guide pin, the first slot extending along at least a portion of a length of the receiver.

The movement control component may further include a pair of guide pins, the heatsink may include a second slot adapted to receive the pair of guide pins, and the first slot may be adapted to restrict the movement path to a first direction and the second slot may be adapted to restrict movement of the heatsink in a second direction that is different from the first direction.

The positioning system may further include an elevation member adapted to position the heatsink at the first position while the position control component is not applying force to the heatsink to move the heatsink to the second position.

The elevation member may include a deformable component adapted to deform to facilitate positioning of the heatsink at the second position.

The thermal conduction channel may include a thermal interface material adapted to fill a gap between the heatsink and the module while the heatsink is in the second position.

A direction of insertion of the module may be different from a direction of travel of the heatsink when moving between the first position and the second position.

The module may be an optical module adapted to establish an operable connection between the hardware component and other hardware components of other devices.

An enclosure may include the receiver and may house the hardware components of the data processing system that may perform the computer-implemented method.

A rack system may include the enclosure to house the hardware components of the data processing system and may perform the computer-implemented method when the computer instructions are facilitated by the hardware components.

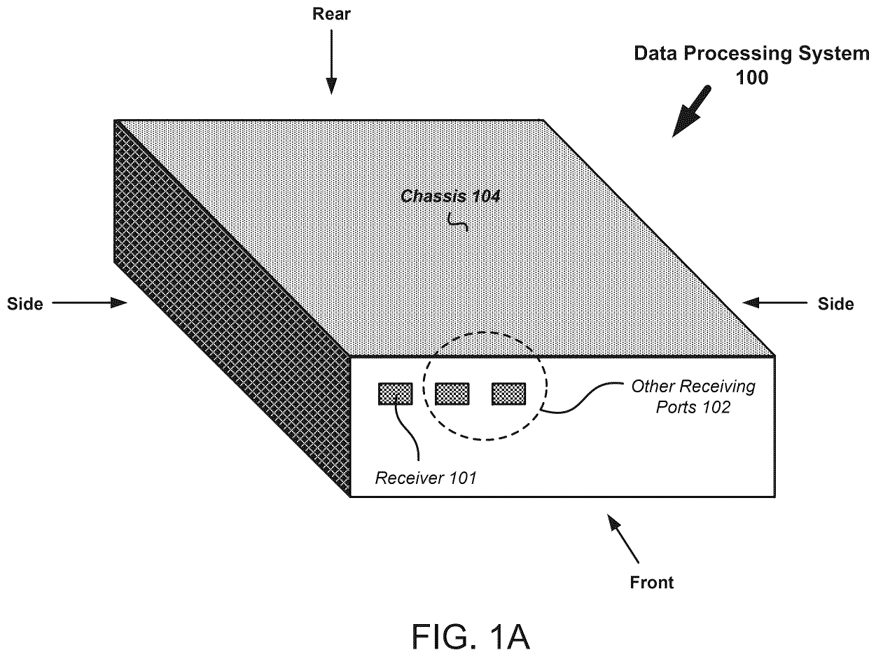

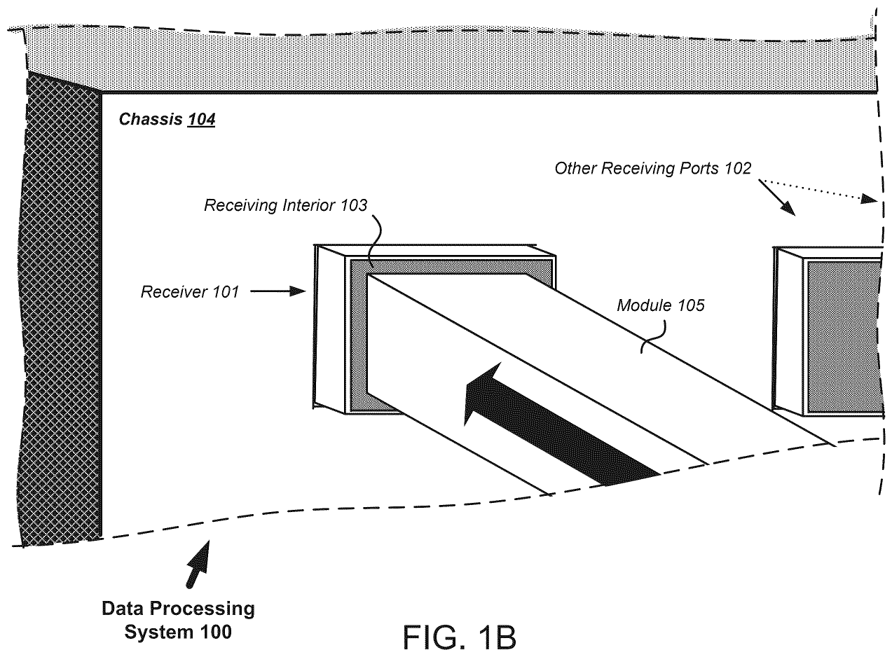

Turning to FIG. 1A, a first diagram illustrating a data processing system (e.g., 100) in accordance with an embodiment is shown. The data processing system shown in FIG. 1A may provide computer implemented services, as discussed below.

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices not to be limited by embodiments discussed herein.

Other types of computer implemented services may be provided by the system shown in FIG. 1A without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services. For example, to facilitate the various functionalities, a hardware component may transmit data to and/or from other devices via various avenues of communication. For example, such avenues of communication may depend on physical operable connections that directly connect multiple hardware components to one another.

To provide its functionality of providing computer implemented services, the data processing system may be implemented by data processing system 100, as shown in FIG. 1A. For example, data processing system 100 may include receiver 101, other receiving ports 102, chassis 104, and/or other types of components not to be limited by embodiments discussed herein. Each of these is discussed briefly below.

Chassis 104 may house various hardware components of data processing system 100. For example, various electronics, power components, and/or other types of components of data processing system 100 (not to be limited by embodiments discussed herein) may be positioned in chassis 104 such that chassis 104 may be adapted to house said components within chassis 104's interior.

By being adapted to house various components, chassis 104 may be further adapted to facilitate placement/positioning of a limited number of the components, the limited number of components being due to limited available cubic space (e.g., limited interior volume of the chassis) as well as a limited quantity of port slots (e.g., connection interfaces such as receiver 101 and/or other receiving ports 102) with which operable connection may be established between data processing system 100 and a component whose connection interface makes complete, physical contact with at least one of the port slots positioned with chassis 104.

Although depicted in FIG. 1A to include such port slots on a front side of chassis 104, it will be appreciated that such port slots may otherwise be positioned on a rear side, and/or any other side, of chassis 104.

To provide its functionality, chassis 104 may be implemented by an enclosure in which at least a portion of physical structures of the various hardware components (e.g., processors, memory, etc.), and/or other types of components of data processing system 100 may be positioned. For example, chassis 104 may facilitate placement and management of the hardware components and/or the other types of components in computing environments such as those discussed herein, chassis 104 being implemented by, for example, a rack mount frame of a rack mount chassis system.

Therefore, by housing various components whose operations may facilitate the various functionalities of data processing system 100 within the limited interior volume of chassis 104 while chassis 104 is mounted in a rack system, hardware components of data processing system 100 may be positioned with the rack and with regard to one another. In such positioning, operable connections between data processing system 100 and the components may be facilitated by physical contact between component connection interfaces and port slots (e.g., receiver 101 and/or other receiving ports 102). For example, such port slots may be implemented by slots positioned with chassis 104 that may include electronic components/connections that when physical contact is made, operable connections may be facilitated.

As previously mentioned, however, these hardware components may generate heat as a byproduct of their operation. More specifically, modules that may be operably connected to data processing system 100 via the previously mentioned port slots (e.g., receiver 101 and/or other receiving ports 102) may generate heat as a byproduct of their facilitating such operable connections.

For additional information regarding how such heat may be generated, and then regulated, refer to the description of FIG. 1B below.

Turning to FIG. 1B, a second diagram illustrating a data processing system (e.g., 100) in accordance with an embodiment is shown. The viewpoint shown in FIG. 1B may be an expanded view of that shown with regard to FIG. 1A and may therefore provide computer implemented services.

As previously discussed, modules (e.g., 105) that may be operably connected to data processing system 100 via the previously mentioned port slots (e.g., receiver 101 and/or other receiving ports 102) may generate heat as a byproduct of their facilitating such operable connections.

For example, imagine a port slot such as receiver 101 positioned with chassis 104 for data processing system 100 is connected to a transceiver module such as module 105, thereby connecting data processing system 100 to a separate device via an operable connection. Further assume that module 105's operation results in significant generation of heat. To decrease the likelihood of damage to the connection (“receiving”) port that is receiver 101, module 105, and/or any other connected components/devices, a heatsink may be positioned with receiver 101, and thermal interface material (TIM) may be positioned between where module 105 may be inserted into receiver 101 (e.g., such insertion being depicted via the bold, black arrow overlapping module 105) and the heatsink to optimize an efficiency associated with a dissipation of heat generated during module 105's operation. For example, as shown in FIG. 1B, module 105 may be shown as being inserted into receiving interior 103. It will be appreciated that without the inclusion of the TIM, sufficient heat dissipation may not be possible, and thus, such operable connections may be highly dependent on the inclusion of the TIM, as well as the TIM's integrity being maintained.

However, due to the desirable “hot-swapping” nature of such modules as module 105 (e.g., being able to easily, and frequently, change out modules operably connected via the connection slot), the receiver 101 (e.g., and even any of other receiving ports 102) may become excessively used. Consequently, such integral components as the TIM positioned with each port slot may become degraded and/or even removed entirely over the course of one or more such “hot-swapping” of such modules as module 105.

To increase a likelihood of enabling the TIM to stay intact throughout such “hot-swapping”, and therefore, increase a likelihood of facilitating and maintaining efficient thermal regulation of data processing system 100, receiver 101 (e.g., the assumed connection port for receiving for such “hot-swapping” modules) may include (i) the heatsink, and (ii) a positioning system to reposition the heatsink as module 105 may be inserted into receiver 101. By including the heatsink and the positioning system, receiver 101 (and/or any of other receiving ports 102) may be adapted to establish operable connection between data processing system 100 and, for example, module 105 without allowing dysregulation of heat generated by such operable connections.

To do so, the positioning system may adapted to automatically transition the heatsink from a first position to a second position during an insertion of a module such as module 105 into chassis 104 of data processing system 100, while in the second position the heatsink being in thermal communication with module 105 via a thermal conduction channel, and while in the first position the heatsink not being in thermal communication with module 105 via the thermal conduction channel

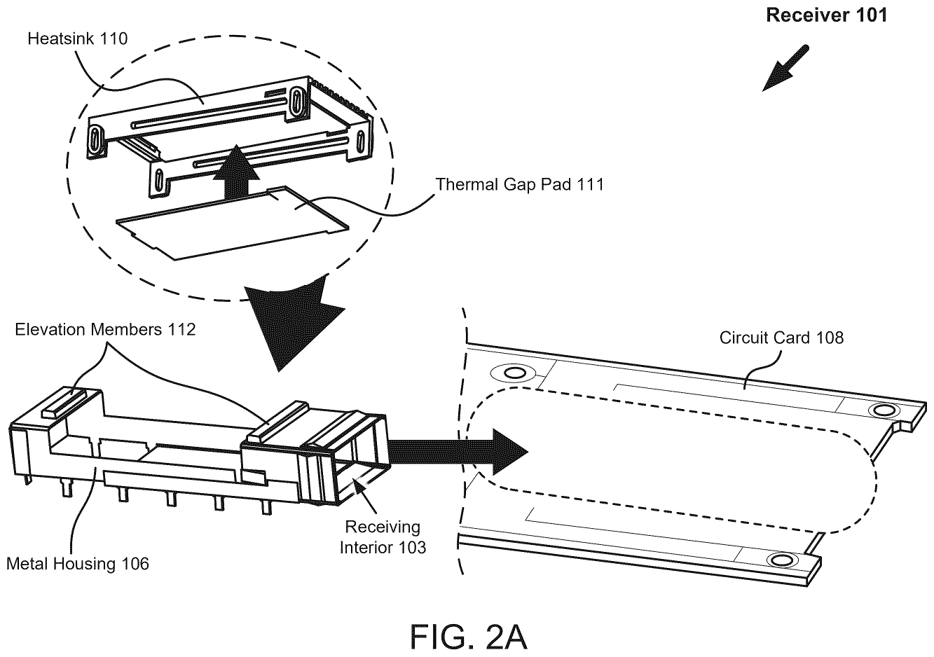

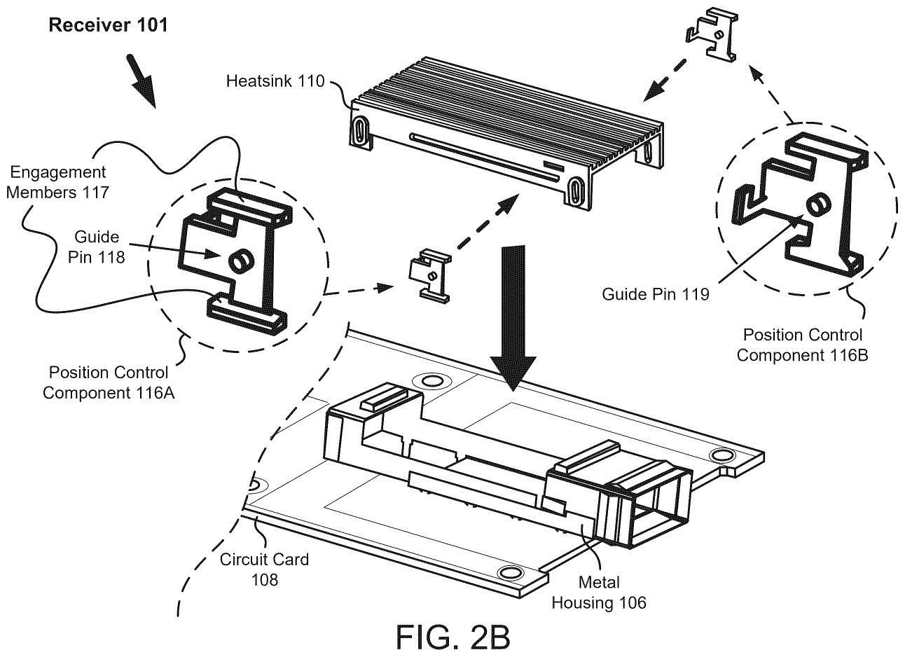

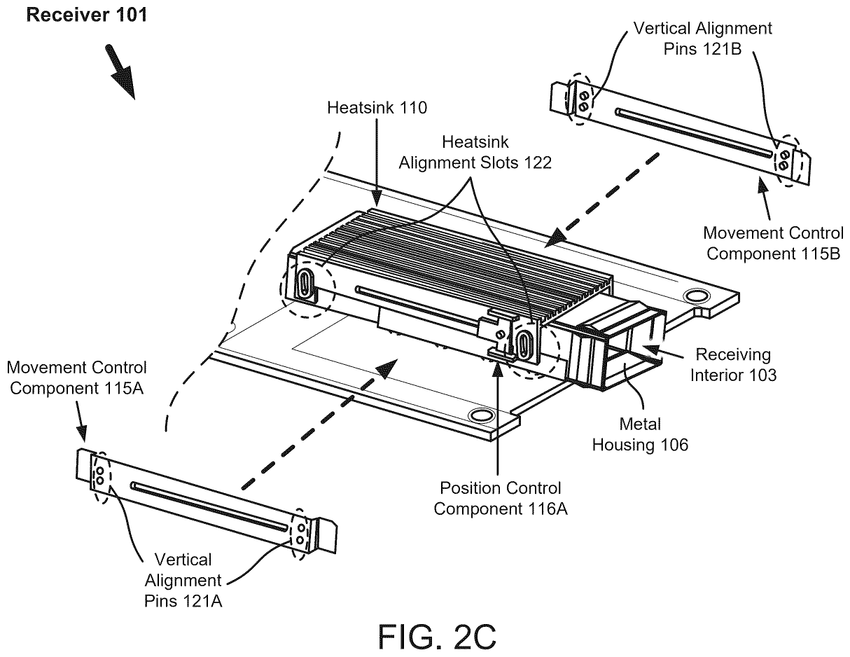

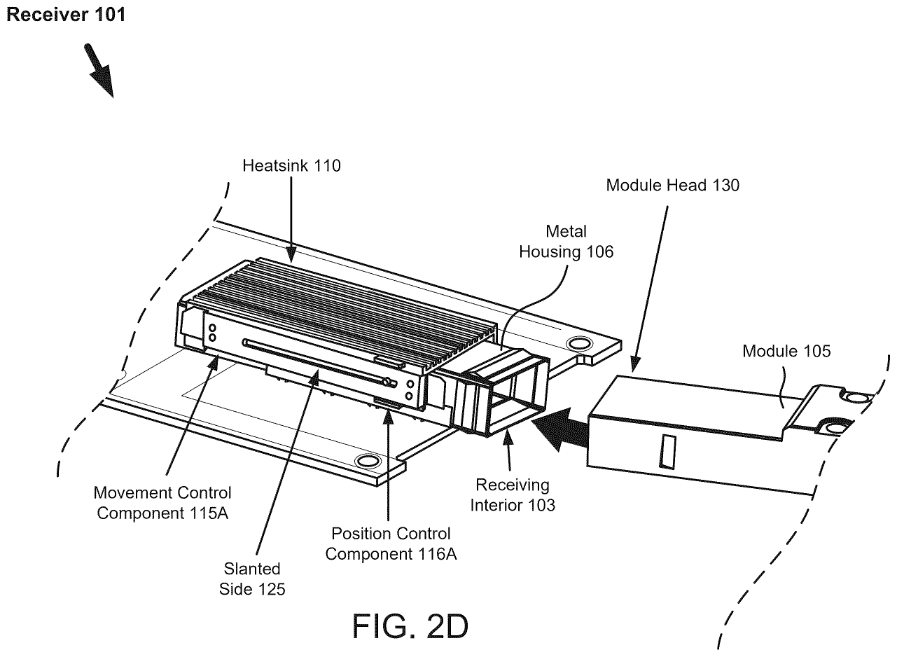

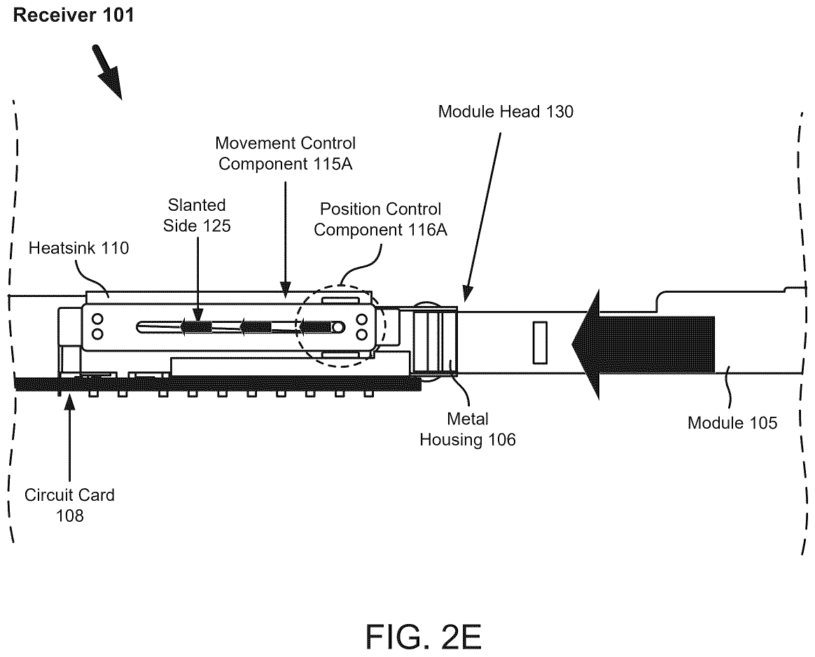

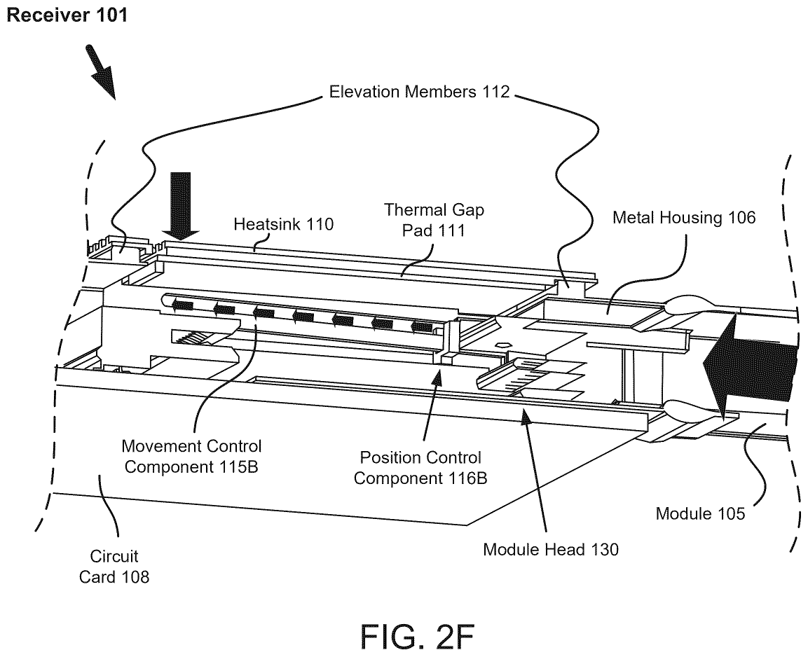

For additional information regarding the positioning system, refer to the descriptions of FIG. 2A-2F below.

Turning to FIG. 2A, a first diagram illustrating a receiver (e.g., 101) in accordance with an embodiment is shown. The receiver shown in FIG. 2A may enable a data processing system (e.g., 100) to provide computer implemented services, as previously discussed.

As previously discussed, receiver 101 (and/or any of other receiving ports 102) may include a heatsink (e.g., 110) and a positioning system.

Heatsink 110 may be adapted to dissipate heat generated by module 105 while module 105 is inserted into receiving interior 103 (also shown in FIG. 1B), receiving interior 103 being encompassed by metal housing 106 that provides a structure for receiver 101. To do so, heatsink 110 may be implemented by a thermally conductive material and may be positioned with thermal gap pad 111. For example, thermal gap pad 111 may increase an efficiency of heat dissipation facilitated by heatsink 110. To do so, thermal gap pad 111 may be implemented by the previously discussed thermal interface material (TIM) to bridge physical contact between module 105 and heatsink 110.

As previously noted, it will be appreciated that without the inclusion of the TIM (e.g., thermal gap pad 111), sufficient heat dissipation may not be possible, and thus, such operable connections between, for example, receiver 101 and module 105 may be highly dependent on the inclusion of thermal gap pad 111, as well as thermal gap pad 111's integrity being maintained. Therefore, such issues involving deprecation of thermal gap pad 111 may be detrimental to the system overall, and thus may be a focused example that embodiments herein discuss to resolve via the positioning system discussed below.

The positioning System may include, as shown positioned with metal housing 106 in FIG. 2A, elevation members 112, adapted to position heatsink 110 at the first position while module 105 is not inserted into receiving interior 103. To do so, elevation members 112 may be implemented by at least one deformable component adapted to deform to facilitate positioning of the heatsink at the second position, such as a foam gasket, to be discussed further below. It will be appreciated that elevation members 112, in addition to positioning heatsink 110 at the first position, may provide a leveling functionality for heatsink 110, and may therefore allow components of receiver 101 to remain level with one another throughout facilitation of operable connections.

Turning to FIG. 2B, a second diagram illustrating a receiver (e.g., 101) in accordance with an embodiment is shown. The receiver shown in FIG. 2B may be receiver 101, mentioned previously, above.

As previously discussed, heatsink 110 may be adapted to dissipate heat generated by module 105 while module 105 is inserted into receiving interior 103, receiving interior 103 being encompassed by metal housing 106 that provides a structure for receiver 101. However, it will be appreciated that metal housing 106, as well as connection interfaces within receiving interior 103, may be positioned with, for example, circuit card 108 as part of the various electronic components housed within chassis 104 (as previously discussed with regard to FIG. 1A). Such positioning may thereby facilitate operable connections between any modules (e.g., module 105) that may be inserted into receiver 101 and hardware components of data processing system 100 housed in chassis 104.

As previously discussed, the positioning system may be adapted to automatically transition the heatsink from a first position to a second position during an insertion of the module into a chassis of the data processing system. To do so, the positioning system may further include (i) movement control components 115A-115B, and (ii) position control components 116A-116B. Each of these is discussed below.

Movement control components 115A-115B may be adapted to limit movement of a position control component (e.g., position control components 116A-116B) to be along a movement path. To do so, movement control components 115A-115B may be implemented by metal guiding brackets on either side of metal housing 106 as shown in FIG. 2B. These metal guiding brackets may include first slots adapted to receive guide pins (e.g., guide pin 118) of position control components 116A-116B, the first slots extending along at least a portion of a length of receiver 101, as shown in FIG. 2B.

Position control components 116A-116B may be adapted to move the heatsink from the first position to the second position while moving along the movement path. For example, to do so, each of position control components 116A-116B may be implemented by (e.g., may include) (i) at least one engagement member (e.g., engagement members 117) to engage with the module during the insertion of the module, the engagement of the engagement member facilitating the movement of the position control component along the movement path, (ii) a guide pin (e.g., guide pin 118) that engages with at least one of movement control components 115A-115B to constrain the movement of position control components 116A-116B to the movement path, and (iii) another guide pin (e.g., guide pin 119) that engages with a slot on heatsink 110 to constrain the repositioning of heatsink 110 from the first position to the second position. Such repositioning may be due to, for example, a slanted side of heatsink 110, discussed further below with regard to FIG. 2D.

For additional information regarding the movement control components and/or the position control components, refer to the following discussions of FIGS. 2C-2F, below.

Turning to FIG. 2C, a third diagram illustrating a receiver (e.g., 101) in accordance with an embodiment is shown. The receiver shown in FIG. 2C may be receiver 101, mentioned previously, above.

As previously discussed, the movement control components 115A-115B may include the first slots adapted to receive guide pins (e.g., guide pin 118) of position control components 116A-116B. Additionally, it will be appreciated that movement control components 115A-115B may further include their own pairs of guide pins, heatsink 110 including second slots and each of the second slots being adapted to receive a respective pair of the pairs of guide pins.

These pairs of guide pins may be implemented by, for example, vertical alignment pins 121A on movement control component 115A and vertical alignment pins 121B on movement control component 115B. The second slots may be implemented by, for example, heatsink alignment slots 122 (e.g., at least for receiving vertical alignment pins 121A).

Therefore, the first slots in movement control components 115A-115B may be adapted to restrict the movement path to a first direction, and the second slots in heatsink 110 may be adapted to restrict movement of heatsink 110 in a second direction that is different from the first direction.

For additional information regarding movement of heatsink 110 (as a module such as module 105 may be inserted into receiver 101), refer to the following discussions of FIGS. 2D-2F below.

Turning to FIG. 2D, a fourth diagram illustrating a receiver (e.g., 101) in accordance with an embodiment is shown. The receiver shown in FIG. 2D may be receiver 101, mentioned previously, above.

As previously discussed, receiver 101 may include heatsink 110 and the previously discussed positioning system. This positioning system, using previously, and respectively, discussed components thereof, may be adapted to automatically transition, for example, heatsink 110 from a first position to a second position during an insertion of module 105 into chassis 104 of data processing system 100. While in the second position heatsink 110 may be in, for example, thermal communication with module 105 via a thermal conduction channel, and while in the first position, for example, heatsink 110 may not be in thermal communication with module 105 via the thermal conduction channel.

As shown in FIG. 2D, insertion of module 105 into receiver 101 may be initiated. At such initiation of the insertion, heatsink 110 may be considered to be at the first position wherein heatsink 110 may not be in thermal communication with module 105 via the thermal conduction channel. Also as shown in FIG. 2D, position control component 116A may still be on the entrance side to receiver 101 while heatsink 110 is at this first position.

Although not previously discussed, it will be appreciated that for such movement between the first and the second positions, heatsink 110 may have a slanted side with regard to the rest of receiver 101. For example, such a side may be implemented by slanted side 125 as shown in FIG. 2D.

As position control component 116A begins moving away from the entrance side of receiver 101, as module 105 interacts with an engagement member of position control component 116A, position control component 116A may move along slanted side 125 thereby moving heatsink 110 toward the second position.

For additional information regarding this movement of heatsink 110 from the first to the second position, refer to the discussions of FIGS. 2E-2F below.

Turning to FIG. 2E, a fifth diagram illustrating a receiver (e.g., 101) in accordance with an embodiment is shown. The receiver shown in FIG. 2E may be receiver 101, mentioned previously, above.

As shown in FIG. 2E, module 105 may be inserted in a direction as shown by a large black arrow. This insertion may cause a force to be implemented onto position control component 116A, wherein position control component 116A may move inward from the entrance side of receiver 101 and further (e.g., deeper) into receiving interior 103, as indicated by the smaller white arrows depicted along the movement path that movement control component 115A limits position control component 116A's movement along.

During such movement of position control component 116A, slanted side 125's interaction with position control component 116A's movement may cause heatsink 110 to be pulled downward towards circuit card 108, resulting in heatsink 110 moving to the second position as module 105 is inserted into receiver 101.

For additional information regarding heatsink 110's movement from the first to the second position, refer to FIG. 2F below.

Turning to FIG. 2F, a sixth diagram illustrating a receiver (e.g., 101) in accordance with an embodiment is shown. The receiver shown in FIG. 2F may be receiver 101, mentioned previously, above. The viewpoint may be different in FIG. 2F to that previously used to provide additional information (e.g., understanding) with regard to component positions and movements.

As shown in FIG. 2F, as module 105 is pushed deeper into receiver 101 (e.g., depicted by the large white arrow shaded with patterned in-fill), module head 130 of module 105 may be pushed to place a force on the engagement member of position control component 116B. By doing so, position control component 116B may follow a movement path depicted by the small white arrows aligned with the first slot of movement control component 115B. As position control component 116B moves along this movement path, heatsink 110 may move downward on top of module 105 (e.g., depicted with the pattern in-filled arrow pointing downward on top of heatsink 110).

By moving this way as module 105 is inserted fully into receiver 101, heatsink 110 may move from the first position, and to the second position, thereby facilitating a thermal conduction channel between heatsink 110 and module 105 while in the second position when there was no thermal conduction channel while heatsink 110 was in the first position.

Additionally, by allowing such repositioning of heatsink 110 by the positioning system, thermal gap pad 111 (e.g., a TIM) may maintain its integrity for any number of hot-swapped modules such as module 105.

It will be appreciated that, as discussed in previous figures, elevation members 112 may reposition heatsink 110 back to the first position as module 105 is removed from receiver 101.

While illustrated in FIGS. 2A-2F with a limited number of specific components, a system may include additional, fewer, and/or different components without departing from embodiments disclosed herein.

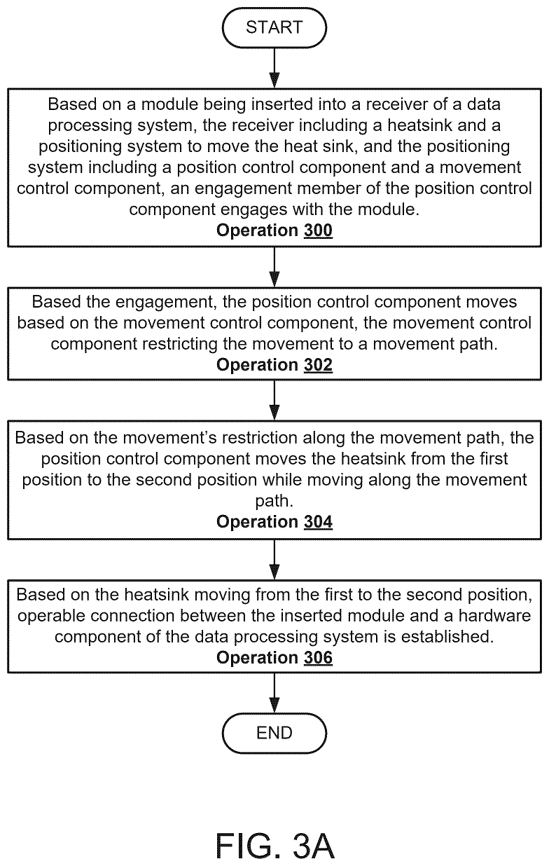

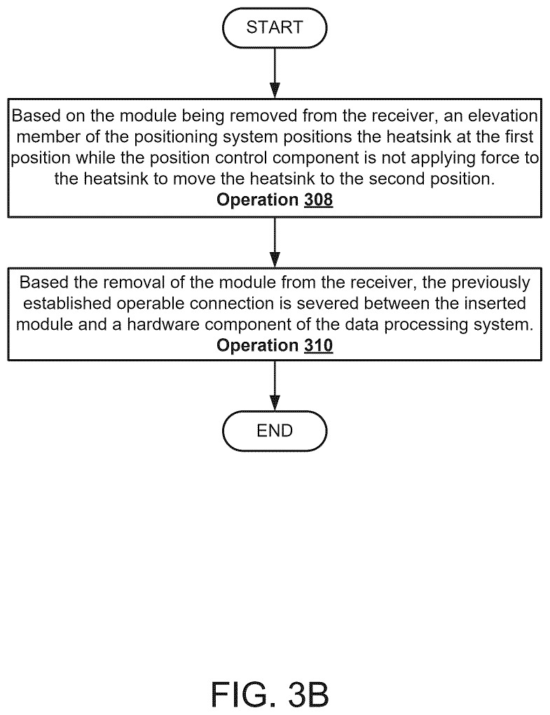

For additional information regarding how the heatsink and positioning system may be utilized to facilitate operable connections between a receiver (e.g., 101) and a module (e.g., 105), refer to the discussion of FIGS. 3A-3B below.

As discussed above, the components of FIGS. 1A-2F may perform and/or otherwise facilitate various methods/processes to manage (operation of) a data processing system (e.g., 100). FIGS. 3A-3B illustrates a method that may be performed and/or otherwise facilitated by the components of the data processing system, previously discussed with regard to FIGS. 1A-2F. In the diagrams discussed below and shown in FIGS. 3A-3B, any of the operations may be repeated, performed in different orders, and/or performed in parallel with, or in a partially overlapping in time manner with, other operations.

Turning to FIG. 3A, a first flow diagram illustrating a method of managing operation of a data processing system in accordance with an embodiment is shown. The method may be performed, for example, by any of the components of the systems shown in FIGS. 1A-2F (e.g., receiver 101). For example, this first flow diagram may be used to discuss an example method of facilitating an operable connection of a module to a hardware component of the data processing system. Therefore, it will be appreciated that, in the following discussion of FIG. 3A, the module is assumed to have at least begun to be inserted into a port slot (e.g., receiver 101) of a data processing system (e.g., 100), and that the module connects to, and or is, a device that is separate from the data processing system.

At operation 300, based on a module being inserted into a receiver of a data processing system, the receiver including a heatsink and a positioning system to move the heatsink, and the positioning system including a position control component and a movement control component, an engagement member of the position control component engages with the module.

The engagement member of the position control component may engage with the module by the module being restricted to an insertion path in which physical contact with the engagement member is unavoidable, and the engagement member be pushed further into the receiver for the module to continue traversing deeper into the receiver as well.

At operation 302, Based the engagement, the position control component moves based on the movement control component, the movement control component restricting the movement to a movement path.

The position control component may move based on the movement control component by way of an automatic mechanical force that causes each sub-component of these components to be moved in manners that depend on one another's movements. For example, and as previously shown in FIGS. 1A-2F, (i) the position control component may include a guide pin that engages with the movement control component to constrain the movement of the position control component to the movement path, the guide pin moving in unison with the engagement component, and (ii) the movement control component may include a first slot adapted to receive the guide pin, the first slot extending along at least a portion of a length of the receiver, the module's pushing of the engagement component further into the receiver causing the guide pin to move in the movement path restricted by the first slot (e.g., further into the receiver as the guide pin and engagement component move in unison with one another).

At operation 304, Based on the movement's restriction along the movement path, the position control component moves the heatsink from the first position to the second position while moving along the movement path.

The position control component may move the heatsink from the first position to the second position by way of similarly dependent (e.g., on proximate sub-component movements) automatic mechanical movement as previously mentioned, the similarly dependent automatic mechanical movement being facilitated by (i) at least a pair of guide pins of the movement control component, (ii) respective mechanical couplings between the heatsink and the position control component as well as the movement control component, and (iii) physical features of the heatsink, as discussed below.

For example, and as previously shown in FIGS. 1A-2F, the movement control component may include a pair of guide pins, and the heatsink may include a second slot adapted to receive the pair of guide pins. The first slot may be adapted to restrict the movement path to a first direction and the second slot may be adapted to restrict movement of the heatsink in a second direction that is different from the first direction (e.g., the heatsink may move along a vertical axis while the position control component may move along a horizontal axis).

By including the coupling via the pair of guide pins, the heatsink may be prevented from moving in the same direction as the position control component, instead, the second slot's slanted shape causing the heatsink's movement in the second direction as the position control component moves. For example, the previously mentioned first position may be a position of the heatsink in which the heatsink is raised up and away from where module may sit within this receiving port that is the receiver. Therefore, when the insertion of the module causes the above-mentioned series of automatic mechanical movements, the heatsink may be automatically forced down towards the module by the respective mechanical couplings. This lowered position, now proximate to the inserting module, may be regarded as the second position.

Thus, the position control component may move the heatsink from the first position to the second position.

At operation 306, based on the heatsink moving from the first to the second position, operable connection between the (now) inserted module and a hardware component of the data processing system is established.

This operable connection may be established by physical contact being facilitated between connection points of the module reaching a connection interface at a furthest point within the receiving port, the connection interface already providing connections to the hardware component of the data processing system. This operable connection may be additionally supported by the intactness of thermal interface material (TIM) on a surface of the heatsink, as well as the heatsink, both being lowered onto the module when the module is inserted to increase an efficiency of heat dissipation for the module as the module operates using the operable connection.

Thus, the operable connection of the module to the hardware component of the data processing system may be facilitated.

For additional information regarding how the heatsink and positioning system may be utilized to sever operable connections between the receiver (e.g., 101) and the module (e.g., 105), refer to FIG. 3B discussed below.

Turning to FIG. 3B, a second flow diagram illustrating a method of managing operation of a data processing system in accordance with an embodiment is shown. The method may be performed, for example, by any of the components of the systems shown in FIGS. 1A-2F (e.g., receiver 101). For example, this second flow diagram may be used to discuss an example method of severing an operable connection (the operable connection facilitated previously above) between a module (e.g., 105) to a hardware component of the data processing system (e.g., the previously mentioned hardware component). Therefore, it will be appreciated that, in the following discussion of FIG. 3B, the module is assumed to have maintained the operable connection but has begun to be removed from the receiver.

At operation 308, based on the module being removed from the receiver, an elevation member of the positioning system positions the heatsink at the first position while the position control component is not applying force to the heatsink to move the heatsink to the second position.

The elevation member of the positioning system may position the heatsink at the first position by the elevation component's conformable nature re-expanding after the heatsinks downward force placing pressure on the elevation component that causes the elevation component to deform. For example, the position control component's release from pressure caused by the module's original insertion into the receiver is now moved out of the receiver instead of into the receiver.

For example, the elevation member may therefore be implemented by a deformable component adapted to deform to facilitate positioning of the heatsink at the second position.

At operation 310, based the removal of the module from the receiver, the previously established operable connection is severed between the inserted module and a hardware component of the data processing system.

The previously established operable connection may be severed by the connections point of the module no longer being in physical contact with the connection interface within the receiving port (the receiver). Additionally, the elevation components positioning of the heatsink back to the first position may enable a safe removal of the module, safe being a term to mean that a structural integrity and/or functionality of any sub-components of the movement control component and/or the position control component (e.g., the TIM) may be maintained/protected from damage due to repetitive physical contact/friction that may otherwise have impacted such sub-components should the positioning system not be included in the receiver.

Thus, to increase efficiency of a data processing system's thermal regulation, a receiving port of the data processing system may include a heatsink topped with a thermal interface material (TIM) and may be positioned to facilitate optimal heat dissipation based on a position of the module with respect to a positioning system integrated with the receiving port and adapted to reposition the heatsink. By providing such adaptable and automatic repositioning of the heatsink (and therefore, the TIM), the TIM may not deteriorate quickly, nor may it degrade with respect to a heat dissipation rate due to effects resulting from constant contact/friction. Thus, hot swappable modules of any type and/or quantity may be repeatedly connected and/or disconnected from such receiving ports with a decreased likelihood of damage or degradation to the relevant components along with an increased likelihood of maintaining (and therefore increasing) efficiency.

Any of the processes and/or components illustrated in and/or discussed with regard to FIGS. 1A-3B may be implemented with and/or used in conjunction with one or more computing devices (e.g., a computing device (e.g., 100) that may be equipped with a receiver (e.g., 101) for receiving a module (e.g., 105), such reception being adapted to establish an operable connection between the computer device and other devices.)

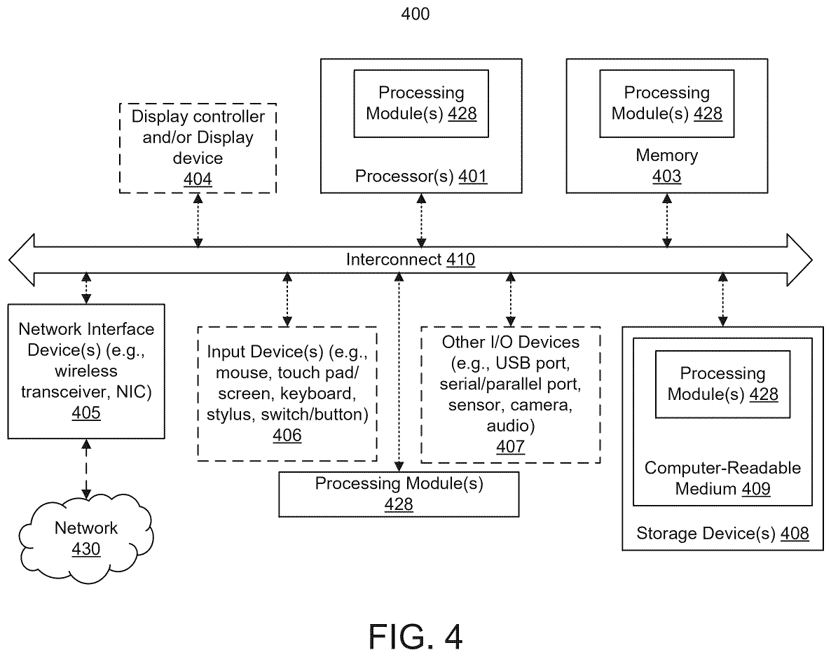

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very-long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as an embedded controller (not shown) may control a keyboard or thermal sensor, dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or (perhaps) more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and (generally) conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system comprising:
a hardware component; and
a receiver for a module to establish an operable connection between the hardware component and the module, the receiver comprising:
a heatsink for dissipating heat generated by the module; and
a positioning system adapted to automatically transition the heatsink from a first position to a second position during an insertion of the module into a chassis of the data processing system, while in the second position the heatsink is in thermal communication with the module via a thermal conduction channel, and while in the first position the heatsink is not in thermal communication with the module via the thermal conduction channel.

2. The data processing system of claim 1, wherein the positioning system comprises:
a movement control component adapted to limit movement of a position control component to be along a movement path.

3. The data processing system of claim 2, wherein the positioning system further comprises:
the position control component adapted to move the heatsink from the first position to the second position while moving along the movement path.

4. The data processing system of claim 3, wherein the position control component comprises:
an engagement member to engage with the module during the insertion of the module, the engagement of the engagement member facilitating the movement of the position control component along the movement path.

5. The data processing system of claim 4, wherein the position control component further comprises:
a guide pin that engages with the movement control component to constrain the movement of the position control component to the movement path.

6. The data processing system of claim 5, wherein the movement control component comprises a first slot adapted to receive the guide pin, the first slot extending along at least a portion of a length of the receiver.

7. The data processing system of claim 6, wherein the movement control component further comprises a pair of guide pins, the heatsink comprises a second slot adapted to receive the pair of guide pins, and the first slot is adapted to restrict the movement path to a first direction and the second slot is adapted to restrict movement of the heatsink in a second direction that is different from the first direction.

8. The data processing system of claim 3, wherein the positioning system further comprises:
an elevation member adapted to position the heatsink at the first position while the position control component is not applying force to the heatsink to move the heatsink to the second position.

9. The data processing system of claim 8, wherein the elevation member comprises a deformable component adapted to deform to facilitate positioning of the heatsink at the second position.

10. The data processing system of claim 1, wherein the thermal conduction channel comprises a thermal interface material adapted to fill a gap between the heatsink and the module while the heatsink is in the second position.

11. The data processing system of claim 1, wherein a direction of insertion of the module is different from a direction of travel of the heatsink when moving between the first position and the second position.

12. The data processing system of claim 1, wherein the module is an optical module adapted to establish an operable connection between the hardware component and other hardware components of other devices.

13. An enclosure for a data processing system comprising:
a chassis adapted to house hardware components of the data processing system;
a receiver for a module to establish an operable connection between a hardware component of the hardware components and the module, the receiver comprising:
a heatsink for dissipating heat generated by the module; and
a positioning system adapted to automatically transition the heatsink from a first position to a second position during an insertion of the module into the chassis, while in the second position the heatsink is in thermal communication with the module via a thermal conduction channel, and while in the first position the heatsink is not in thermal communication with the module via the thermal conduction channel.

14. The enclosure of claim 13, wherein the positioning system comprises:
a movement control component adapted to limit movement of a position control component to be along a movement path.

15. The enclosure of claim 14, wherein the positioning system further comprises:
the position control component adapted to move the heatsink from the first position to the second position while moving along the movement path.

16. The enclosure of claim 15, wherein the positioning system further comprises:
an elevation member adapted to position the heatsink at the first position while the position control component is not applying force to the heatsink to move the heatsink to the second position.

17. A rack system, comprising:
a rack; and
a data processing system to be housed in the rack, the data processing system comprising:
a hardware component; and
a receiver for a module to establish an operable connection between the hardware component and the module, the receiver comprising:
a heatsink for dissipating heat generated by the module; and
a positioning system adapted to automatically transition the heatsink from a first position to a second position during an insertion of the module into a chassis of the data processing system, while in the second position the heatsink is in thermal communication with the module via a thermal conduction channel, and while in the first position the heatsink is not in thermal communication with the module via the thermal conduction channel.

18. The rack system of claim 17, wherein the positioning system comprises:
a movement control component adapted to limit movement of a position control component to be along a movement path.

19. The rack system of claim 18, wherein the positioning system further comprises:
the position control component adapted to move the heatsink from the first position to the second position while moving along the movement path.

20. The rack system of claim 19, wherein the positioning system further comprises:
an elevation member adapted to position the heatsink at the first position while the position control component is not applying force to the heatsink to move the heatsink to the second position.
